(19) United States
(12) Patent Application Publication
(10) Pub. No.: US 2008/0233727 A1
(43) Pub. Date: Sep. 25, 2008

(54) Method of manufacturing semiconductor device

(75) Inventor: Jin Hwan Lee, Icheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR INC.

(21) Appl. No.: 11/976,350

(22) Filed: Oct. 24, 2007

(30) Foreign Application Priority Data
Mar. 23, 2007 (KR) 10-2007-0028693

(51) Int. Cl. H01L 21/3205

(52) U.S. Cl. 438/586; 257/E21.294

(57) ABSTRACT

Disclosed is a method for manufacturing a semiconductor device. More specifically, in the invention, a gate pattern is formed and then an interlayer insulating pattern burying the space between the gate patterns is formed to ensure the region into which a landing plug contact hole has to be opened, thereby avoiding a problem in that the landing plug contact hole is not opened when forming the landing plug contact hole in a subsequent process. As a result, a failure that may occur in a subsequent test process can be avoided and further a current drivability of a gate, a tWR feature and a timing margin are ensured and thereby improve the device features.

### CROSS-REFERENCES TO RELATED APPLICATIONS

This application is based upon and claims the benefit of priority to Korean Patent Application No. 10-2007-0028693, filed on Mar. 23, 2007, the contents of which are incorporated herein by reference.

### BACKGROUND OF THE INVENTION

The present invention relates to a method of manufacturing a semiconductor device, and more particularly, to a method of manufacturing a semiconductor device in which a gate pattern is formed and then an interlayer insulating pattern burying the space between the gate patterns is formed so that a region into which a landing plug contact hole is scheduled to open is ensured, thereby avoiding the contact hole being not opened when forming the landing plug contact in a subsequent process. As a result, a failure that may occur in a subsequent test process can be avoided and further device features can be improved by ensuring tWR characteristics and a timing margin.

As the semiconductor memory device is highly integrated, the practical area of a unit cell is reduced together with a reduction of contact size to arrange more unit cells on a defined area when manufacturing a highly integrated semiconductor device.

Accordingly, there has been a difficulty in the electrical connection between the upper and lower patterns, particularly between a substrate bonding region and a bit line, and a substrate bonding region and capacitor. In consideration of this, in a recent semiconductor manufacturing process, a landing plug poly is formed on the bonding region through a self aligned contact (hereinafter, referred to as “SAC”) and thereby enabling a stable electrical connection between the upper and lower patterns by this landing plug poly.

FIGS. 1a and 1b are sectional views of a method of manufacturing a semiconductor device according to the prior art.

Referring to FIG. 1a, a plurality of gate patterns 125 is formed over a semiconductor substrate 100 provided with an active region and an isolation region 105. Here, the gate patterns 125 is preferably formed of a gate polysilicon layer 110, a gate metal layer 115 and a gate hard mask layer 120. Subsequently, a lining insulating film 130 of a predetermined thickness is formed over the substrate including the gate patterns 125. Next, an interlayer insulating film 140 and a hard mask layer 150 are formed on the whole surface of the semiconductor substrate 100 provided with the gate patterns 125, and a photo resist pattern 160 is formed over the hard mask layer 150.

With reference to FIG. 1b, the hard mask layer 150 is etched with the photo resist pattern 160 as an etching mask to form a hard mask pattern (not shown). In subsequence, the photo resist pattern 160 is removed. After that, the interlayer insulating film 140 is etched with the hard mask pattern (not shown) as an etching mask to form a landing plug contact hole 165 and then the hard mask pattern (not shown) is removed. At this time, when etching the interlayer insulating film 140 for forming the landing plug contact hole 165, the interlayer insulating film 140 between the gate patterns 125 is not etched entirely so that there arises a problem in that the landing plug contact hole 165 is “not opened” as “A” in FIG. 1b.

According to the method of manufacturing a device in the prior art mentioned-above, there arises a problem in that as an aspect ratio of a landing plug contact hole increases with a high integration of a device, the bottom of the landing plug contact hole is “not opened” wholly when etching the interlayer insulating film for forming the landing plug contact hole.

The state of the contact hole not being entirely opened as mentioned above induces a device failure to reduce a current drivability of a gate and thus deteriorates characteristics of a write recovery time tWR.

### SUMMARY OF THE INVENTION

The method of manufacturing a semiconductor device according to the invention is characterized in that it comprises steps of a method of manufacturing a semiconductor device comprising steps of: providing a semiconductor substrate comprising an active region and an isolation region; forming a plurality of gate patterns over the active region and the isolation region; forming a first interlayer insulating pattern between the gate patterns in the active region; forming a second interlayer insulating film over the first interlayer pattern and semiconductor substrate; etching the second interlayer insulating film until the first interlayer insulating pattern is exposed; removing the first interlayer insulating pattern to expose the substrate between gate patterns in the active region, whereby forming a landing plug contact hole; and filling the landing plug contact hole with a conductive material to form a landing plug contact.

The first interlayer insulating pattern and second interlayer insulating film are formed of substances having different etching selectivity ratios, respectively.

The second interlayer insulating film is formed with a thickness of about 5000 to about 7000 Å.

The step of removing the first interlayer insulating pattern is performed using a wet etching method.

The step of forming the landing plug contact further comprises: forming a polysilicon layer the semiconductor substrate including the landing plug contact hole and performing a planarization process until the gate patterns is exposed.

The step of further comprising forming a lining insulating film over the gate patterns.

### BRIEF DESCRIPTION OF THE DRAWINGS

FIGS. 1a 1b are sectional views of a method of manufacturing a semiconductor device according to the prior art; and

FIGS. 2a to 2i are sectional views of a method of manufacturing a semiconductor device according to the invention.

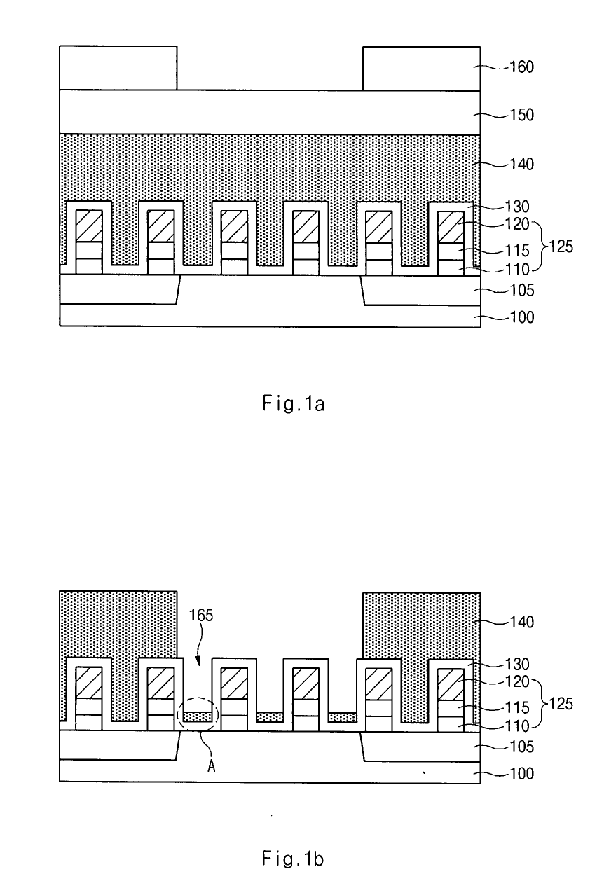

### DESCRIPTION OF EMBODIMENTS

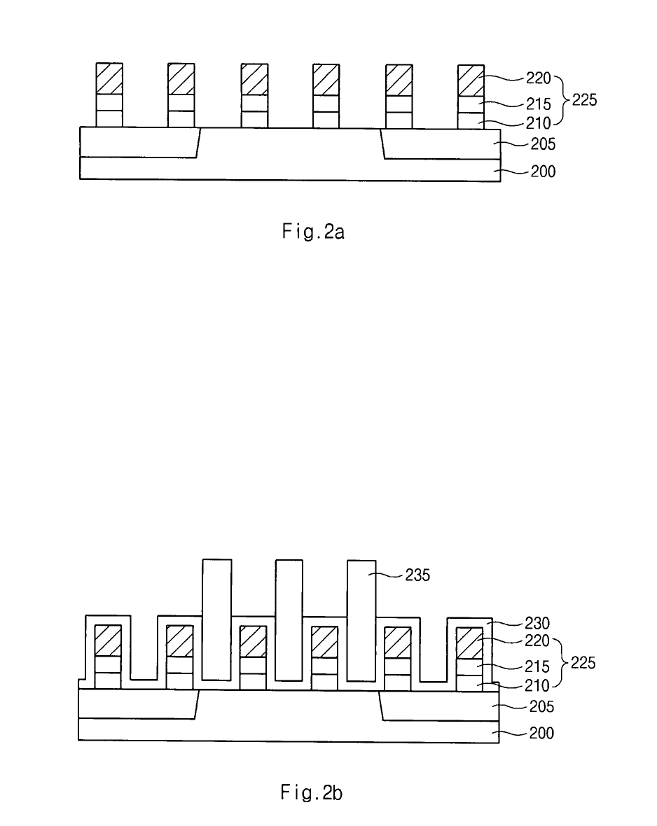

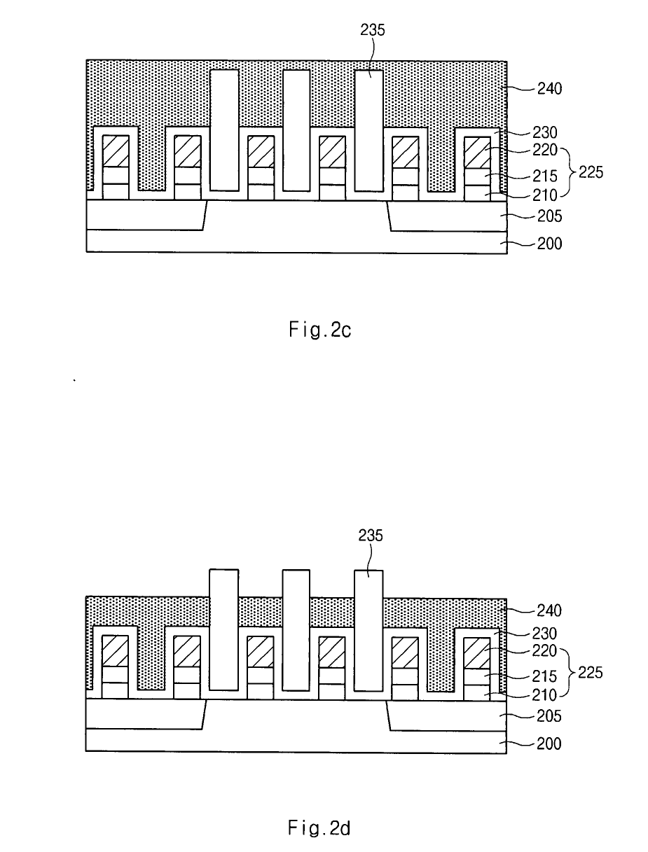

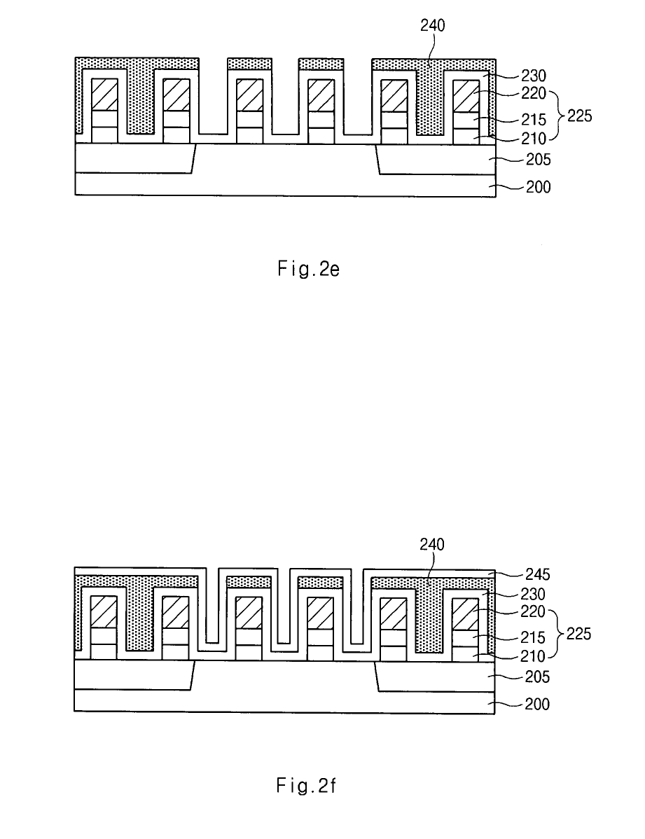

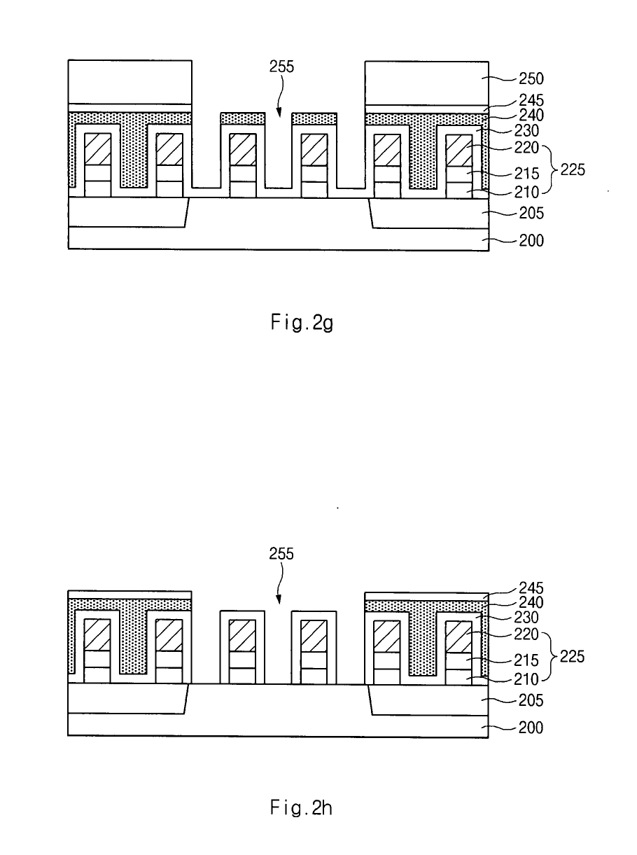

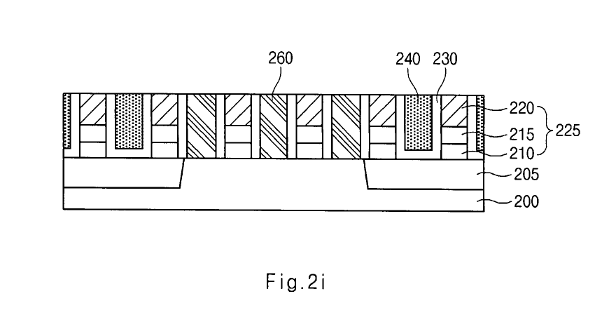

FIGS. 2a to 2i are sectional views of a method of manufacturing a semiconductor device according to the invention.

Referring to FIG. 2a, a gate oxide layer (not shown), a gate ploysilicon layer 210, a gate metal layer 215 and a gate hard mask layer 220 are formed as a stacked structure over a semiconductor substrate 200 provided with an active region and an isolation region 205. Next, the stacked structure is patterned to form a plurality of gate patterns 225. Here, the gate metal layer 215 is formed using any one of tungsten, tungsten silicide and a combination thereof, and the gate hard mask layer 220 is preferably formed of a nitride layer.

With reference to FIG. 2b, a lining insulating film 230 of a predetermined thickness is formed over the semiconductor substrate 200 including the gate patterns 225, and the planarized first interlayer insulating film (not shown) and photo resist (not shown) are formed. Subsequently, a photolithography process and a developing process are performed using an exposing mask provided with a shielding pattern on a landing plug contact scheduled region such that a first photo resist pattern (not shown) is formed on the landing plug contact scheduled region.

The first interlayer insulating film (not shown) is etched with the first photo resist pattern (not shown) as an etching mask and a first interlayer insulating pattern 235 is formed on the landing plug contact scheduled region. Here, the first interlayer insulating pattern 235 is formed to be buried between the gate patterns 225 in the active region, on which the landing plug contact is scheduled to form, and is preferably formed higher than the gate patterns 225. Referring to FIG. 2C, the first photo resist pattern (not shown) is removed and then a second interlayer insulating film 240 is formed over the first interlayer pattern 235 and semiconductor substrate 200. At this time, the second interlayer insulating film 240 is formed preferably of about 5000 Å to about 7000 Å in thickness based on the surface of the semiconductor substrate 200. Additionally, the second interlayer insulating film 240 and the first interlayer insulating pattern 235 are formed preferably of substances having different etching selectivity ratios, respectively.

With reference to FIG. 2d, an etch back process is performed to etch the second interlayer insulating film 240. At this time, when etching the second interlayer insulating film 240, the first interlayer insulating pattern 235 is not etched due to the big difference of the etching selectivity ratio thereof. Here, the second interlayer insulating film 240 is etched preferably until a portion of the first interlayer insulating pattern 235 is to be exposed.

Referring to FIG. 2e, the first interlayer insulating pattern 235 formed on the landing plug contact scheduled region is removed to expose the landing plug contact plug scheduled region between the gate patterns 225 in the active region. Here, the removing process of the first interlayer insulating pattern 235 is preferably performed using a wet etching method. At this time, at least a portion of the second interlayer insulating film 240 is also removed preferably to a height not exposing the gate patterns 225.

With reference to FIG. 2f, a hard mask layer 245 of a predetermined thickness is formed over the semiconductor substrate 200 surface including the landing plug contact scheduled region.

Referring to FIG. 2g, a second photo resist (not shown) is formed on the resulting surface of FIG. 2f above and a second photo resist pattern 250 exposing the landing plug contact region is formed by performing photolithography and development processes using an exposing mask for a landing plug contact. Subsequently, the exposed hard mask layer 245 is etched with the second photo resist pattern 250 as an etching mask to form a hard mask layer 245 pattern to define a landing plug contact hole 255.

With reference to FIG. 2h, the second photo resist pattern 250 is removed and then is etched back with the hard mask layer 245 pattern as an etching mask to remove the lining insulating film 230 formed on the bottom of a landing plug contact hole between the gate patterns 225 so that the landing plug contact hole 255 is formed exposing the semiconductor substrate 200.

Referring to FIG. 2i, the hard mask layer 245 pattern is removed and a polysilicon layer is formed over the semiconductor substrate 200 including the landing plug contact hole 255. Next, a planarization process is performed until the gate hard mask layer 220 over the gate patterns 225 is exposed such that a landing contact plug 260 is formed.

In the method of manufacturing a semiconductor device according to the invention, a gate pattern is formed and then an interlayer insulating pattern burying the space between the gate patterns is formed to ensure the region into which a landing plug contact hole has to be opened, thereby avoiding a problem in that the landing plug contact hole is not opened when forming the landing plug contact hole in a subsequent process.

As a result, a failure that may occur in a subsequent test process can be avoided and further a current drivability of a gate, the tWR feature and timing margin, are ensured and thereby improve the device features.

The above embodiments of the present invention are illustrative and not limiting. It will be apparent to those skilled in the art that various modifications and variations may be made in the present invention without departing from the spirit and scope consistent with the invention as defined by the appended claims.

What is claimed is:

1. The method of manufacturing a semiconductor device comprising steps of: providing a semiconductor substrate comprising an active region and an isolation region;
forming a plurality of gate patterns over the active region and the isolation region
forming a first interlayer insulating pattern between the gate patterns in the active region;
forming a second interlayer insulating film over the first interlayer insulating pattern and the semiconductor substrate;
etching the second interlayer insulating film until the first interlayer insulating pattern is exposed;
removing the first interlayer insulating pattern to expose the semiconductor substrate between gate patterns in the active region, whereby forming a landing plug contact hole; and
filling the landing plug contact hole with a conductive material to form a landing plug contact.

2. The method of claim 1, wherein the first interlayer insulating pattern and the second interlayer insulating film are formed of substances having different etching selectivity ratios, respectively.

3. The method of claim 1, wherein the second interlayer insulating film is formed with a thickness of about 5000 Å to about 7000 Å.

4. The method of claim 1, wherein the step of removing the first interlayer insulating pattern is performed using a wet etching method.

5. The method of claim 1, wherein the step of forming the landing plug contact further comprises:
forming a polysilicon layer over the semiconductor substrate including the landing plug contact hole; and
performing a planarization process until the gate patterns is exposed.

6. The method of claim 1, further comprising forming a lining insulating film over the gate patterns.
